(19) United States
(12) Patent Application Publication
(10) Pub. No.: US 2005/0087329 A1
(43) Pub. Date: Apr. 28, 2005

(54) Heat dissipation module with a pair of fans

(76) Inventors: Jie Zhang, Dongguan City (CN); Min Zhang, Dongguan City (CN)

Correspondence Address: MOLEX INCORPORATED, 2222 WELLINGTON COURT, LISLE, IL, 60532, US

(21) Appl. No.: 10/957,227

(22) Filed: Oct. 1, 2004

(30) Foreign Application Priority Data
Oct. 3, 2003 (TW) 92217811

(51) Int. Cl. F24H 3/06; H05K 7/20

(52) U.S. Cl. 165/104.33; 165/80.3; 165/122

(57) ABSTRACT

A heat dissipation module with a pair of fans is described. The heat dissipation module has a heat dissipation fin, a heat pipe and a pair of fans. The present invention enhances heat dissipation efficiency. The present invention has a fin group having a plurality of heat dissipation fins in stack. A first and a second supporting mechanism with a plurality of threaded holes are set on opposite sides of the fin group. A first and a second fans are individually set on opposite sides of the fin group. Each of the first and the second fans has holes corresponding to the threaded holes of the first and the second supporting mechanism. Therefore, the first and the second fans can be built at opposite sides by using the first and the second supporting mechanism.

### FIELD OF THE INVENTION

The present invention relates to a heat dissipation module with a pair of fans, and especially to a module with a pair of fans on opposite sides of the fin group. The two fans are set to blow air in the same direction, and the present invention can suck in cold air and blow out hot air to increase convection, thereby enhancing the efficiency of heat dissipation.

### BACKGROUND OF THE INVENTION

With advances in electronic engineering, electrical products produce much more heat. Due to the closed casing of the electrical products, heat dissipation is also more difficult than before dissipation successfully and efficiently can help electrical products have a higher performance. Therefore, the dissipation system is increasingly important. Usually, a designer produces a heat dissipation system with a larger area at the surface of the products to be dissipated.

However, the dissipating devices are not modularized, so the fans are not easily set on the electrical products and require an excessive mechanism. Due to the lack of modularization, the producers only set one fan at one side of the electrical device, so the air sent by the fan cannot pass through heat dissipation device as effectively and provide poor dissipating efficiency.

### SUMMARY OF THE INVENTION

One object of the present invention is to modularize a heat dissipation system and increase convection efficiency by using a pair of fans.

Another object of the present invention is also to enhance heat dissipation efficiency by using a special heat pipe and a heat board with the heat pipe to further increase the efficiency of heat dissipation.

To achieve the objects mentioned above, the present invention provides a heat dissipation module with a pair of fans the heat dissipation module, including a fin group having a plurality of heat dissipation fins in stack; a first and a second supporting mechanism with a plurality of holes set in opposite sides of the fin group; and first and second fans individually set on opposite sides of the fin group. Each of the first and the second fans has hole body corresponding to the holes of the first and the second supporting mechanism. The first and the second fans are set on opposite sides by using the first and the second supporting mechanism.

### BRIEF DESCRIPTION OF THE DRAWINGS

FIG. 1 is a three-dimensional decomposition diagram of the present invention;

FIG. 2 is a three-dimensional decomposition diagram after some composition of the present invention;

FIG. 3 shows a three-dimensional composition diagram of the present invention;

FIG. 4 shows a two-dimensional front diagram of the present invention;

FIG. 5 shows a diagram of a top view of the present invention;

FIG. 6 shows a temperature field diagram of the present invention using a single fan or using two fans to blow air in the opposite direction; and

FIG. 7 shows a temperature field diagram of the present invention using two fans to blow air in the same direction.

### DETAILED DESCRIPTION OF THE PREFERRED EMBODIMENTS

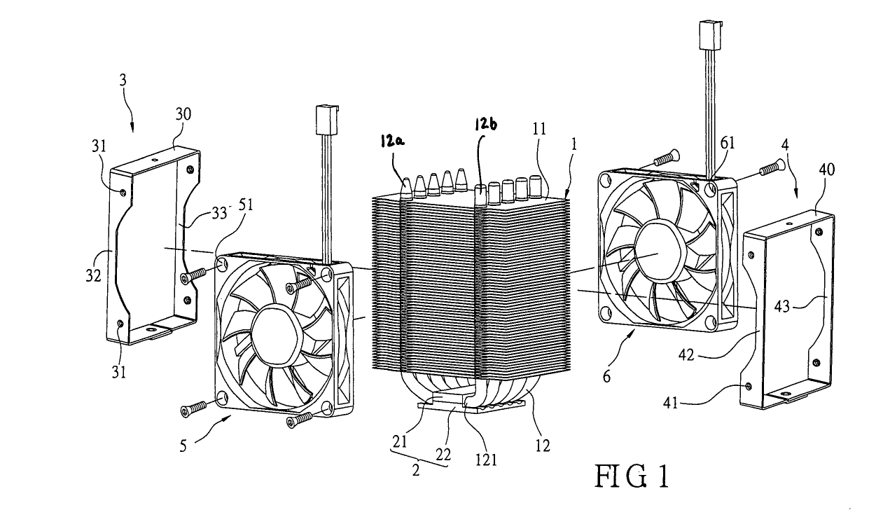

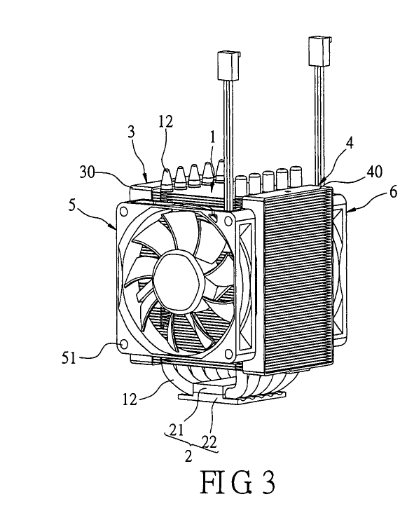

Reference is made to FIGS. 1-5. The present invention provides a heat dissipation module with a pair of fans, including a fin group 1, first and second supporting mechanisms 3, 4 and first and second fans 5, 6.

The fin group 1 includes a plurality of heat dissipation fins 11 in a stack, a plurality of heat pipes 12 in a U-shape, and a heat board 2. Each heat pipe 12 has two free terminals 12a, 12b stretching in the same direction. The heat pipe 12 also has a non-enveloped portion 121 between two free terminals 12a, 12b. The two free terminals of the heat pipe 12 penetrate through each heat dissipation fin 11 of the fin group 1 in the same direction to allocate each heat dissipation fin 11. The heat board 2 is located at the non-enveloped portion 121 of the each heat pipe 12. Therefore, heat produced by electrical device can be to the heat board, into the heat pipe, into the fins and eventually dissipated to the surrounding environment.

The heat board 2 can take many forms. The figures of present invention show one including a cover 21, facing inward and near the fin group 1, and also comprising a seat 22 facing outward. A portion of the heat pipe 12 is enveloped by the cover 21 and the seat 22. The cover 21 and the seat 22 can match each other. Therefore, heat produced by electrical device can be transferred to each heat dissipation fin 11.

The first and the second supporting mechanisms 3, 4 are each fixed on opposite sides of the fin group 1 by any known method. The first and the second supporting mechanism 3, 4 also have a plurality of threaded holes 31, 41 in order to set the first and the second fans 5, 6 at one or another opposite side of the fin group to enhance convection efficiency.

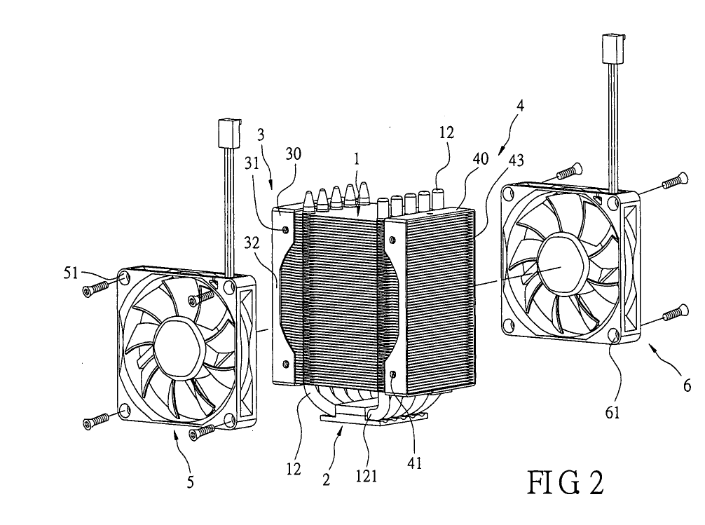

The first and the second supporting mechanism 3, 4 are preferably a first and a second building frame 30, 40. A front side 32, 42 and a back side 33, 43 of the first and the second building frame 30, 40 have a plurality of threaded holes 31, 41. The first and the second building frames 30, 40 are each fixed at one opposite side by using the frames surround the fin group 1 (the front side and the back side as shown in FIG. 2). The direction of the screws of the threaded holes 31, 41 of the first and the second building frames 30, 40 are perpendicular to the left and the right sides of the fin group 1.

The first and the second fans 5, 6 have a plurality of threaded holes 51, 61 in the peripheries thereof, respectively. The first and the second fans 5, 6 are independently set at opposite sides (the left side and the right side) of the fin group 1. Therefore, the first fan 5 cross connects the front sides 32, 42 of the first and the second building frames 30, 40. Additionally, the second fan 6 cross connects the back sides 33, 43 of the first and the second building frames 30, 40. A plurality of screws are screwed into the threaded holes 51, 61 of each fan and in the corresponding threaded holes 31, 41 of the building frames 30, 40.

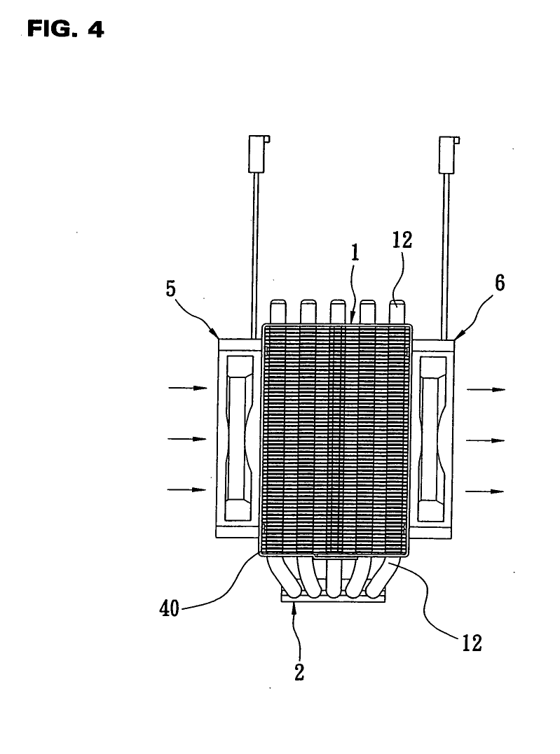

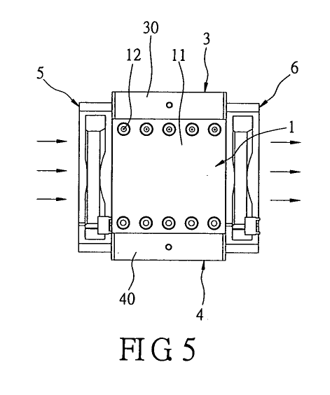

Reference is made to FIG. 4 and FIG. 5. The first and the second fans 5, 6 are located at opposite sides (left side and right side) of the fin group, and the two fans are set to blow air in the same direction (suck or blow air at the same time). Therefore, the present invention can enhance convection efficiency of the fin group 1 by sucking in cold air and blowing out hot air.

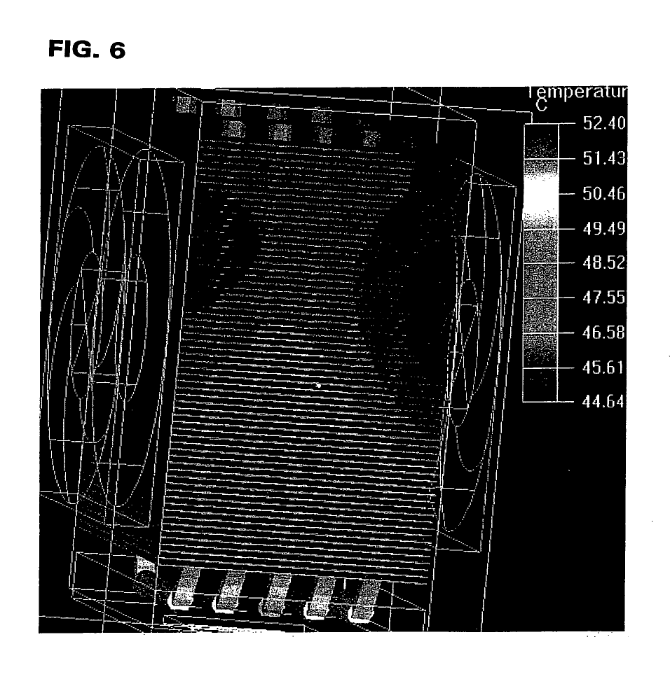

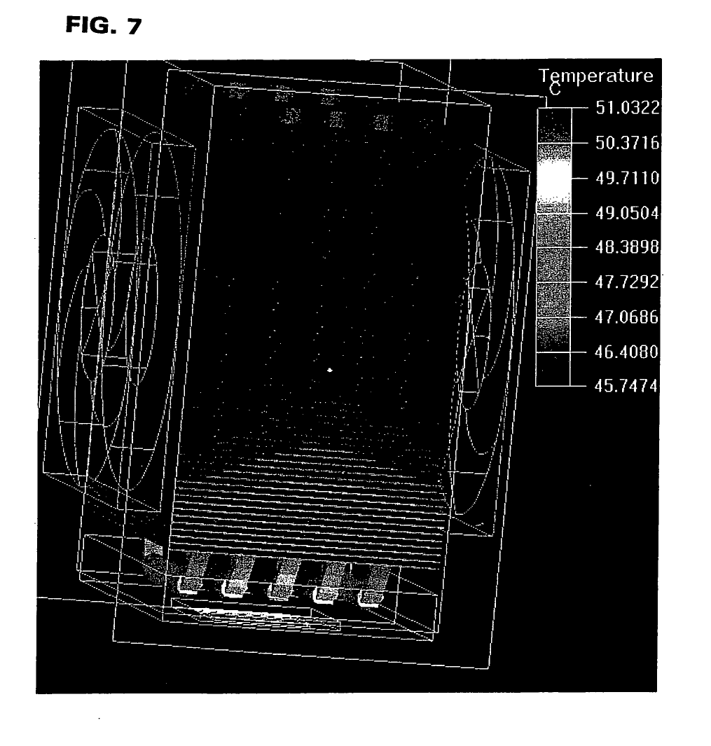

Reference is made to the temperature field charts in FIG. 6 and FIG. 7. When one of the first fan and the second fan 5, 6 starts, the air cannot pass through the fin group 1 easily, so heat dissipation efficiency is poor. When the first and the second fans 5, 6 start together, one of the two fans suck cold air into the fin group 1 and the other fan blows cold air into the fin group 1 at the same time. The cold air masses entering from the two sides collide with each other, and the efficiency of heat dissipation is still poor. As FIG. 6 shows, the two methods both have many middle temperature or high temperature areas that are not in blue color.

As FIG. 7 shows, when the first and the second fans 5, 6 suck and blow air in the same direction, that is, suck cold air in and blow hot air out of fin group 1, only a small area near the heat board 2 is at middle temperature that is not in blue color. That means when the two fans suck in and blow out air in the same direction and are combined with the heat board 2 and the heat pipe 12, heat dissipation efficiency can be increased.

One advantage of the present invention is modularization. The fans can be built and set conveniently. The producer can produce a single fan system or a two fan system with regard for the cost.

Another advantage of the present invention is high heat dissipation efficiency. The two fans module can enhance heat dissipation efficiency by convection and greatly increase dissipation efficiency by adding heat board 2 and the specially installed heat pipe 12. When the present invention has the double dissipation equipment mentioned above, heat dissipation efficiency can reach top level.

There has thus been described a new, novel and heretofore unobvious heat dissipation module with a pair of fans that eliminate the aforesaid problem in the prior art. Furthermore, those skilled in the art will readily appreciate that the above description is only illustrative of specific embodiments and examples of the invention. The invention should therefore cover various modifications and variations made to the herein-described structure and operations of the invention, provided the fall within the scope of the invention as defined in the following appended claims.

1. A heat dissipation module with a pair of fans, including:
a fin group having a plurality of heat dissipation fins;
a first and a second supporting mechanism set on opposite sides of the fin group, wherein each the first and the second supporting mechanisms; and
first and second fans individually set on opposite sides of the fin group, wherein each of the first and the second fans are attached to the first and the second supporting mechanism, and the first and the second fans are set on opposite sides by using the first and the second supporting mechanism.

2. The heat dissipation module with a pair of fans as claimed in claim 1, wherein the first and the second supporting mechanisms have a plurality of threaded holes corresponding to threaded holes on the first and second fans to attach the fans to the supporting mechanisms with screws.

3. The heat dissipation module with a pair of fans as claimed in claim 1, wherein the first and the second fans blow air in the same direction through the heat sink dissipating fins.

4. The heat dissipation module with a pair of fans as claimed in claim 1, wherein the fin group further comprising a plurality of heat pipes, the heat pipes are U-shaped and two free terminals penetrate in a same direction through the heat dissipation fins of the fin group.

5. The heat dissipation module with a pair of fans as claimed in claim 4, wherein the fin group further comprising a heat board, and the heat board is set on the non-enveloped portion between two free terminals of the heat pipe.

6. The heat dissipation module with a pair of fans as claimed in claim 1, further including a heat board and at least one heat pipe, wherein the heat board comprises a cover facing inward and located near the fin group, and also comprises a seat facing outward, the non-enveloped portion of the heat pipe being enveloped by the cover and the seat.

7. The heat dissipation module with a pair of fans as claimed in claim 1, wherein the heat dissipating fins are individual fins that are formed into a stack.

8. The heat dissipation module with a pair of fans as claimed in claim 1, further including a heat pipe that is at least partially enveloped by the fin group.

9. The heat dissipation module with a pair of fans as claimed in claim 8, wherein at least a portion of the heat pipe extends above the fin group.

10. The heat dissipation module with a pair of fans as claimed in claim 8, wherein the heat pipe is generally “U” shaped.
